(19) United States
(12) Patent Application Publication
(10) Pub. No.: US 2026/0226611 A1
(43) Pub. Date: Aug. 6, 2026

(54) HALIDE-FREE CO-REACTANTS FOR RUTHENIUM FILM DEPOSITION

(71) Applicant: Applied Materials, Inc., Santa Clara, CA (US)

(72) Inventors: Chandan Kr Barik, Singapore (SG); Feng Q. Liu, San Jose, CA (US); Andrea Leoncini, Singapore (SG)

(73) Assignee: Applied Materials, Inc., Santa Clara, CA (US)

(21) Appl. No.: 19/042,181

(22) Filed: Jan. 31, 2025

(51) Int. Cl. C23C 16/18; C07F 15/00; C23C 16/04; C23C 16/455; H01L 21/768

(52) U.S. Cl. CPC C23C 16/18; C07F 15/0046; C23C 16/042; C23C 16/45553; H10W 20/033; H10W 20/056; H10W 20/076; H10W 20/084

(57) ABSTRACT

Methods of depositing ruthenium-containing films are described. Methods of manufacturing interconnect structures as part of a microelectronic device fabrication process are also described. The methods include forming a dielectric layer including at least one feature defining a gap having sidewalls and a bottom on a substrate. The method may further include forming a blocking layer on the bottom by exposing the substrate to a blocking compound; selectively depositing a ruthenium-containing film on the sidewalls; removing the blocking layer; and performing a gap fill process to fill the gap with a gap fill material.

### TECHNICAL FIELD

Embodiments of the disclosure generally relate to methods of depositing ruthenium-containing films. In particular, embodiments of the disclosure are directed to methods of depositing ruthenium-containing films for high aspect ratio structures and for barrier, liner, and channel material applications in back-end-of-line (BEOL) processes.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

Ruthenium (Ru) and ruthenium-based films have attractive material and conductive properties. These films have been proposed and tested for applications from front end to back end parts of semiconductor devices. Commercially viable approaches to forming ruthenium films use halide-based co-reactants or precursors and/or high temperatures. Deposition of ruthenium metal films for back end of the line (BEOL) interconnects, however, requires a halide-free process with a thermal budget below 400° C. Halide contamination may affect device performance and hence require additional removal procedures. There is, therefore, a need in the art for halide-free processes to form ruthenium metal and ruthenium-based films.

### SUMMARY

One or more embodiments of the disclosure are directed to a method of depositing a ruthenium-containing film. In some embodiments, the method comprises exposing a semiconductor substrate to a ruthenium-containing precursor and a reactant to form the ruthenium-containing film, the ruthenium-containing precursor having a general formula (I) L₁L₂Ru, wherein L₁ is a benzene substituted with at least one alkyl group, L₂ is diene, and the reactant comprises one or more of an sp-hybridized N-containing ligand, an sp2-hybridized N-containing ligand, an sp3-hybridized N-containing ligand, a mixed-hybridized N-containing ligand, an alcohol, a silane, a borane, and other reactant.

Further embodiments of the disclosure are directed to a method of manufacturing a microelectronic device. In some embodiments, the method comprises forming a dielectric layer on a substrate, the dielectric layer including at least one feature defining a gap having sidewalls and a bottom; forming a blocking layer on the bottom; selectively depositing a ruthenium-containing film on the sidewalls by exposing the substrate to a ruthenium-containing precursor and a reactant, the ruthenium-containing precursor having a general formula (I) L₁L₂Ru, wherein L₁ is a benzene substituted with at least one alkyl group, L₂ is diene, and the reactant comprising one or more of an sp-hybridized N-containing ligand, an sp2-hybridized N-containing ligand, an sp3-hybridized N-containing ligand, a mixed-hybridized N-containing ligand, an alcohol, a silane, a borane, and other reactants; removing the blocking layer; and performing a gap fill process to fill the gap with a gap fill material comprising one or more of copper (Cu), cobalt (Co), ruthenium (Ru), tungsten (W), or ruthenium (Ru).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method in accordance with one or more embodiments of the disclosure.

FIG. 1A illustrates a cross-sectional schematic view of a substrate in accordance with one or more embodiments of the disclosure;

FIG. 1B illustrates a cross-sectional schematic view of a substrate in accordance with one or more embodiments of the disclosure;

FIG. 1C illustrates a cross-sectional schematic view of a substrate in accordance with one or more embodiments of the disclosure;

FIG. 2A illustrates a process flow diagram of a method of manufacturing a microelectronic device in accordance with one or more embodiments of the disclosure;

FIG. 2B illustrates a cross-sectional schematic view of a microelectronic device including a gap having sidewalls and a bottom with a blocking layer formed on the bottom of the gap in accordance with one or more embodiments of the disclosure;

FIG. 2C illustrates a ruthenium-containing film selectively deposited on the sidewalls of the gap of FIG. 2B in accordance with one or more embodiments of the disclosure;

FIG. 2D illustrates removal of the blocking layer formed in FIG. 2B in accordance with one or more embodiments of the disclosure; and

FIG. 2E illustrates a gap fill process filling the gap of FIG. 2B with a gap fill material in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Embodiments of the disclosure provide halide-free processes which result in conductive ruthenium films at temperatures less than 350° C. More specifically, provided are halide-free co-reactants for the deposition of ruthenium metal films by CVD and ALD using a ruthenium-containing precursor having the general form L₁L₂Ru, where L1 is a benzene derivative with alkyl groups, e.g., methyl, ethyl, propyl, isopropyl on benzene, where L2 is diene, such as, but not limited to butadiene, cyclobutadiene, isoprene, 1,3-pentadiene, cyclohexadiene, 1,5-cyclooctadiene, and the reactant comprising be one or more of an sp-hybridized precursor. The halide-free co-reactants react with the ruthenium-containing precursor of general formula (I) at room temperature and result in ruthenium metal on the surface of semiconductor substrates. The reactivity of the halide-free co-reactants was confirmed by wet chemistry experiments. The halide-free co-reactants have been to be very volatile, liquid, and stable for an extended period of time at a delivery temperature by thermogravimetric analysis (TGA) and nuclear magnetic resonance (NMR) spectroscopy.

The reactants or co-reactants of one or more embodiments are substantially free of halide. As used herein, the term “substantially free” means that there is 0% of halogen, on an atomic basis, in the reactant or co-reactant. In some embodiments, the ruthenium-containing film is substantially free of halide, and there is 0% of halide, on an atomic basis, in the ruthenium-containing film.

According to one or more embodiments, the method uses an atomic layer deposition (ALD) process or a chemical vapor deposition (CVD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

As used in this specification and the appended claims, the terms “precursor”, “reactant”, “reactive gas”, and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

Without intending to be bound by theory, it is thought that the presence of halides in the structure of the reactant can pose challenges, as halide contamination may affect device performance and hence require additional removal procedures. Halides bind strongly to metals, requiring higher thermal budget, or the use of additional reagents for its removal. Additionally, halide can redeposit and poison other metal surfaces.

Previously, commercially viable approaches to form ruthenium-containing films use halide-based co-reactants or precursors and/or high temperature. Thus, one or more embodiments provide halide-free reactants, resulting in less contamination of the ruthenium-containing film, and less damage to neighboring films in the semiconductor structures, while maintaining strong device performance and shorter processing times.

Ruthenium (Ru) containing films can be formed by atomic layer deposition or chemical vapor deposition for many semiconductor applications. One or more embodiments of the disclosure advantageously provide processes for atomic layer deposition or chemical vapor deposition to form ruthenium-containing films on a semiconductor substrate. As used in this specification and the appended claims, the term “ruthenium-containing film” refers to a film that comprises ruthenium atoms and has greater than or equal to about 1 atomic % ruthenium, greater than or equal to about 2 atomic % ruthenium, greater than or equal to about 3 atomic % ruthenium, greater than or equal to about 4 atomic % ruthenium, greater than or equal to about 5 atomic % ruthenium, greater than or equal to about 10 atomic % ruthenium, greater than or equal to about 15 atomic % ruthenium, greater than or equal to about 20 atomic % ruthenium, greater than or equal to about 25 atomic % ruthenium, greater than or equal to about 30 atomic % ruthenium, greater than or equal to about 35 atomic % ruthenium, greater than or equal to about 40 atomic % ruthenium, greater than or equal to about 45 atomic % ruthenium, greater than or equal to about 50 atomic % ruthenium, or greater than or equal to about 60 atomic % ruthenium.

In some embodiments, the ruthenium-containing film comprises one or more of ruthenium metal (elemental ruthenium), ruthenium oxide (RuOₓ), ruthenium metal (elemental ruthenium), ruthenium carbide (RuCₓ), ruthenium carbonitride (RuCₓN_{y}), ruthenium silicide (RuSiₓ), ruthenium carbosilicide (RuCₓSi_{y}), ruthenium sulfide (RuSₓ), ruthenium carbosulfide (RuCₓS_{y}), ruthenium nitride (RuNₓ), ruthenium phosphide (RuPₓ), or ruthenium carbophosphide (RuCₓP_{y}).

The skilled artisan will recognize that the use of molecular formula, e.g., ruthenium oxide (RuOₓ), ruthenium carbide (RuCₓ), ruthenium carbonitride (RuCₓN_{y}), ruthenium silicide (RuSiₓ), ruthenium carbosilicide (RuCₓSi_{y}), ruthenium sulfide (RuSₓ), ruthenium carbosulfide (RuCₓS_{y}), ruthenium nitride (RuNₓ), ruthenium phosphide (RuPₓ), or ruthenium carbophosphide (RuCₓP_{y}), does not imply a specific stoichiometric relationship between the elements but merely the identity of the major components of the film. For example, RuCₓ refers to a film whose major composition comprises ruthenium (Ru) atoms and carbon (C) atoms. In some embodiments, the major composition of the specified film (i.e., the sum of the atomic percent of the specified atoms) is greater than or equal to about 95%, 98%, 99% or 99.5% of the film, on an atomic basis.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Ruthenium is a proposed material for integration owing to its high melting point (ability to withstand high current densities), exceptional density, and ability to conduct electrical current. Ruthenium and ruthenium-containing films have attractive material and conductive properties.

The ruthenium-containing films according to one or more embodiments can advantageously be used in memory and logic applications such as, for example, a barrier layer, metal liner, and/or channel material. The ruthenium-containing film according to one or more embodiments can advantageously extend the metal fill and capping applications to advanced nodes, such as enabling conductive metal reflow, e.g., one or more of copper (Cu), cobalt (Co), tungsten (W), ruthenium (Ru), and/or ruthenium (Ru) reflow, in 3 nm node, 2 nm node, 1.4 nm node, and beyond, low resistivity in the middle-of-line (RuL) and back-end of line (BEOL), and memory applications. The ruthenium-containing films according to one or more embodiments can advantageously be used in high aspect ratio structures in BEOL processes.

Embodiments of the present disclosure also provide methods of manufacturing interconnect structures in a microelectronic device fabrication process. Some embodiments of the disclosure provide methods for improving performance of interconnects. Interconnects comprise metal lines that transfer current within the same device layer, and metal vias that transfer current between layers. These metal lines and metal vias are formed with conductive metal such as one or more of copper (Cu), cobalt (Co), ruthenium (Ru), tungsten (W), or ruthenium (Ru) in gaps formed within the device. In one or more embodiments, a dielectric layer comprises at least one feature defining a gap including sidewalls and a bottom. In one or more embodiments, the gap comprises the metal lines and the metal vias. In one or more embodiments, each of the metal lines have a sidewall and a bottom. In one or more embodiments, each of the metal vias have a sidewall and a bottom. As used herein, unless specified otherwise, reference to the “bottom of the gap” is intended to mean the bottom of the metal via, which is nearest the substrate.

In one or more embodiments, microelectronic devices described herein comprise at least one top interconnect structure that is interconnected to at least one bottom interconnect structure. Embodiments of the present disclosure provide microelectronic devices and methods of manufacturing microelectronic devices that improve performance of interconnects, for example, reducing via resistance.

One or more embodiments are directed to a method of manufacturing a microelectronic device. The method comprises: forming a dielectric layer on a substrate, the dielectric layer including at least one feature defining a gap having sidewalls and a bottom; forming a blocking layer on the bottom; selectively depositing an ruthenium-containing film on the sidewalls; removing the blocking layer; and performing a gap fill process to fill the gap with a gap fill material comprising one or more of copper (Cu), cobalt (Co), ruthenium (Ru), tungsten (W), or ruthenium (Ru).

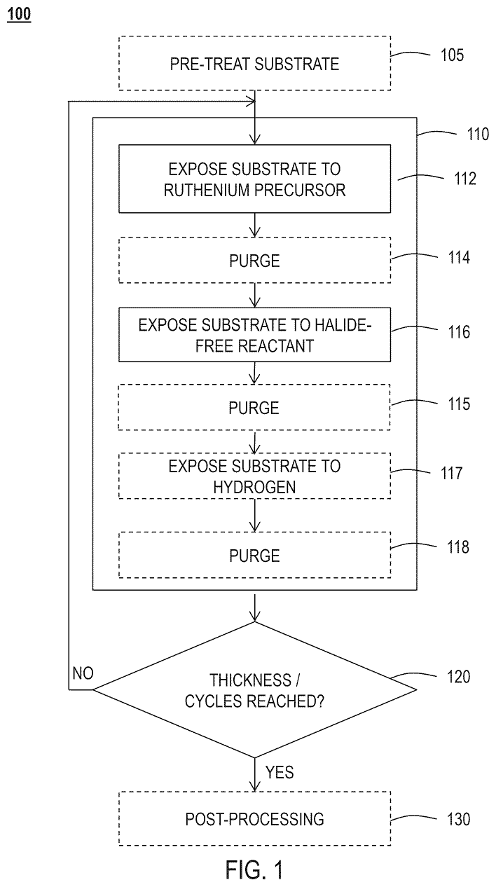

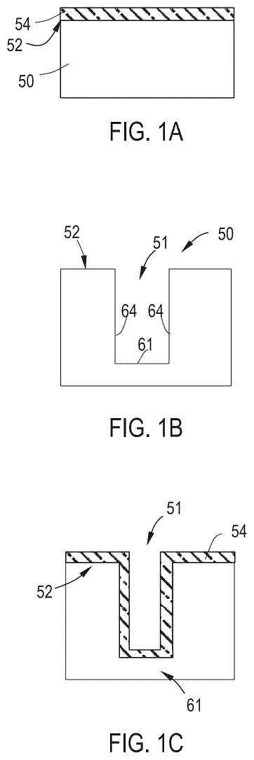

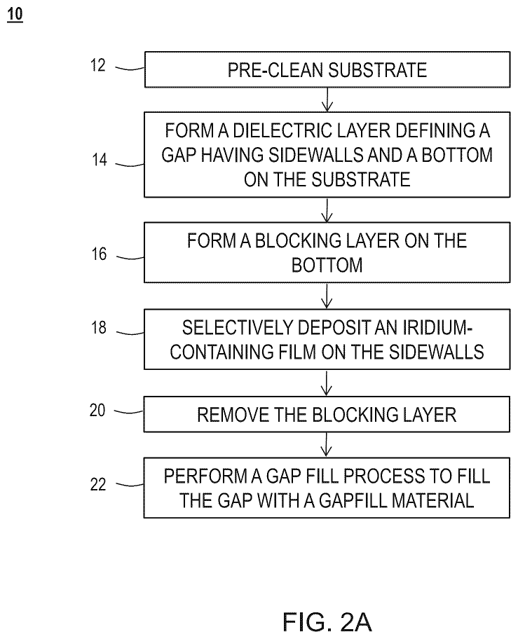

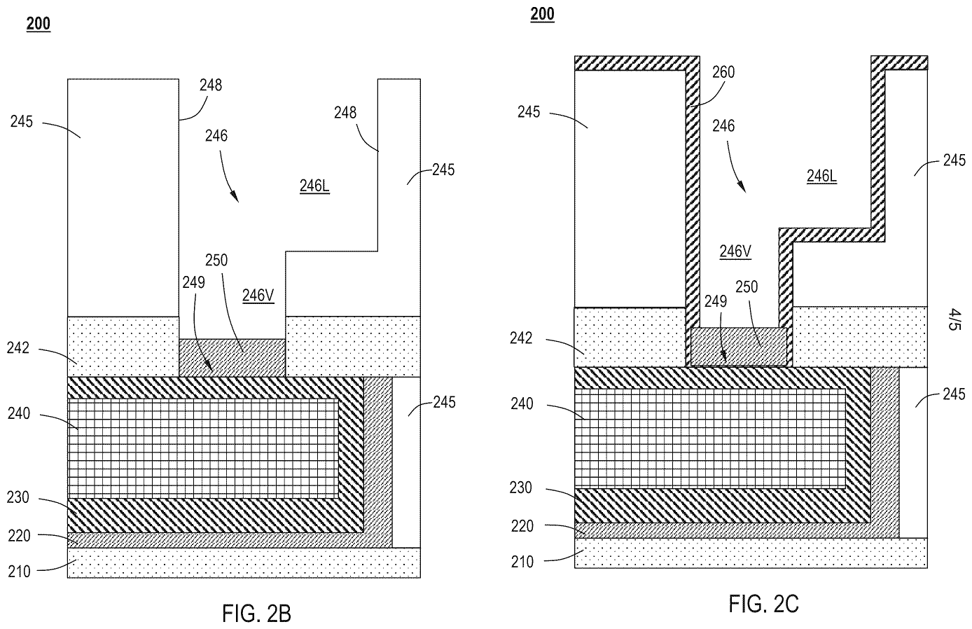

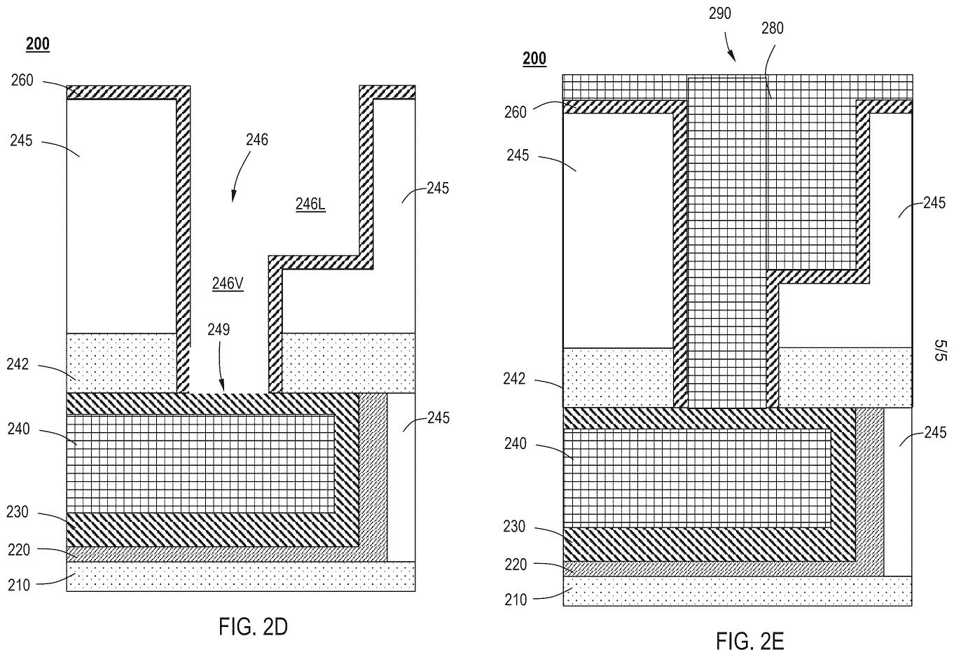

Methods of depositing ruthenium-containing films are described with reference to FIGS. 1 and 1A-1C. FIGS. 1A-1C illustrate cross-sectional schematic views of a substrate 50. Methods of depositing ruthenium-containing films in a microelectronic device fabrication process are described with reference to FIGS. 2A-2E. FIG. 2A is a process flow diagram of an exemplary method 10 of manufacturing a microelectronic device 200. FIGS. 2B-2E illustrate stages of manufacture of the microelectronic device 200 during the method 10 of FIG. 2A.

Embodiments of the disclosure provide methods of depositing ruthenium-containing films that have desired crystallinity, grain size, continuity, and electrical conductivity properties for use as a channel material, liner or barrier layer in the miniaturize and scaling of integrated circuits.

The methods described herein, e.g., method 100, generally refer to methods of manufacturing microelectronic devices and, more particularly, refer to methods of manufacturing interconnect structures as part of a microelectronic device fabrication process. Accordingly, it will be appreciated by the skilled artisan that one or more additional operations needed to complete the fabrication of a microelectronic device are known to the skilled artisan and are within the scope of the present disclosure without undue experimentation.

With reference to FIG. 1, one or more embodiments of the disclosure are directed to a method 100 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film.

In some embodiments, the method 100 includes a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 105.

At deposition 110, a process is performed to deposit a ruthenium-containing film on the substrate (or substrate surface). The deposition process can include one or more operations to form the ruthenium-containing film on the substrate. In operation 112, the substrate (or substrate surface) is exposed to a ruthenium-containing precursor of general formula (I) to deposit a precursor film on the substrate (or substrate surface). The ruthenium-containing precursor of general formula (I) can be any suitable ruthenium-containing compound that can react with (i.e., adsorb or chemisorb onto) the substrate surface to leave a ruthenium-containing species on the substrate surface.

In one or more embodiments, the ruthenium-containing precursor has the general formula (I) L₁L₂Ru, where L₁ is any suitable benzene derivative substituted with at least one alkyl group on the benzene. In one or more embodiments, the alkyl group may be selected from one or more of as methyl, ethyl, propyl, isopropyl, and the like. In one or more embodiments, L₂ is a diene, such as, but not limited to, butadiene, cyclobutadiene, isoprene, 1,3-pentadiene, cyclohexadiene, 1,5-cyclooctadiene, and the like. In one or more specific embodiments, the ruthenium-containing precursor comprises a (isoprene) (toluene) ruthenium-containing precursor. In one or more embodiments, the ruthenium-containing precursor is reacted with a reactant comprising be one or more of an sp-hybridized precursor.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the ruthenium-containing layer, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the ruthenium-containing layer may be at least partially formed thereon. For example, in some embodiments, a layer comprising a metal, a nitride, an oxide, or the like, or combinations thereof may be disposed on the substrate and may have the ruthenium containing layer formed upon such layer or layers.

At operation 114, the processing chamber is optionally purged to remove unreacted ruthenium-containing precursor, unreacted reactant, reaction products and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of ruthenium-containing precursor, unreacted reactant, reaction products and by-products by any suitable technique including, but not limited to, moving the substrate through a gas curtain to a portion or sector of the processing chamber that contains none or substantially none of the ruthenium-containing precursor, unreacted reactant, reaction products and by-products. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas comprises one or more of hydrogen (H₂), nitrogen (N₂), helium (He), and argon (Ar).

At operation 116, the substrate (or substrate surface) is exposed to a halide-free reactant to form one or more of a ruthenium-containing film on the substrate. The halide-free reactant can react with the ruthenium-containing species on the substrate surface to form the ruthenium-containing film.

In one or more embodiments, the halide-free reactant can be selected from any suitable ligand. In one or more embodiments, the halide-free reactant may be one or more of an sp-hybridized N-containing ligand, a sp2-hybridized N-containing ligand, a sp3-hybridized N-containing ligand, a mixed-hybridized N-containing ligand, an alcohol, a silane, a borane, and the like.

The sp-hybridized N-containing ligand may be any suitable sp-hybridized N-containing ligand. In one or more embodiments, the sp-hybridized N-containing ligand may be selected from:

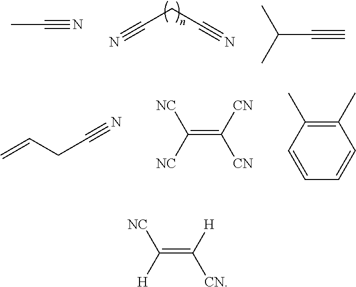

The sp2-hybridized N-containing ligand may be any suitable sp2-hybridized N-containing ligand. In one or more embodiments, the sp2-hybridized N-containing ligand may be selected from one or more of:

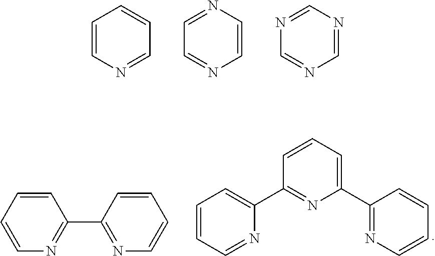

The sp3-hybridized N-containing ligand may be any suitable sp3-hybridized N-containing ligand. In one or more embodiments, the sp3-hybridized N-containing ligand may be selected from one or more of:

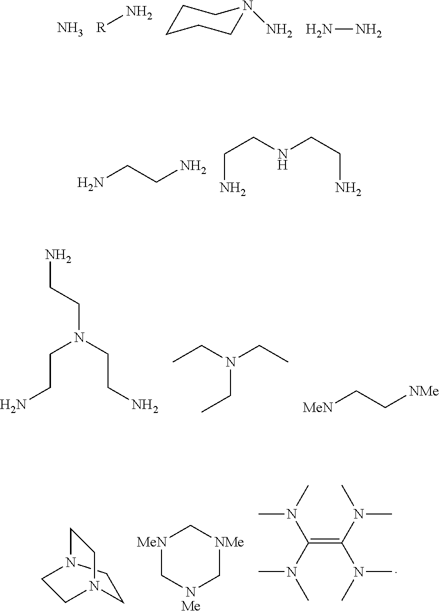

The mixed-hybridized N-containing ligand may be any suitable mixed-hybridized N-containing ligand. In one or more embodiments, the mixed-hybridized N-containing ligand may be selected from:

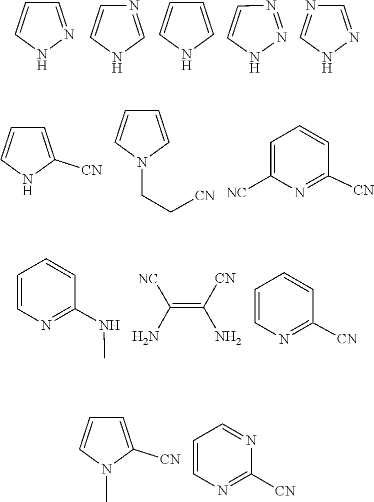

The alcohol may be any suitable alcohol. In one or more embodiments, the alcohol may be selected from R—OH where R comprises an alkyl or aryl group containing from 1 to 10 carbon atoms.

The silane may be any suitable silane. In one or more embodiments, the silane may be selected from

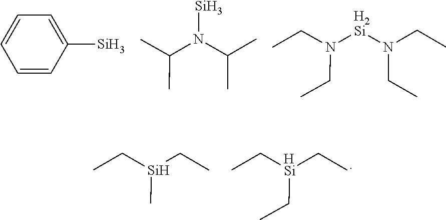

The borane may be any suitable borane. In one or more embodiments, the borane may be selected from:

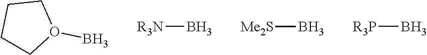

where R independently comprises an alkyl or aryl group containing from 1 to 10 carbon atoms.

In one or more embodiments, other possible reactants may include

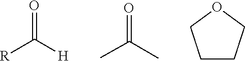

where R comprises an alkyl or aryl group containing from 1 to 10 carbon atoms.

Unless otherwise indicated, the term “lower alkyl,” “alkyl,” or “alk” as used herein alone or as part of another group includes both straight and branched chain hydrocarbons, containing 1 to 20 carbons, or 1 to 10 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

The halide-free reactant may be selected from one or more of acetonitrile, malononitrile, succinonitrile, glutaronitrile, adiponitrile, tertiarybutyl isocyanide, allyl nitrile, tetracyano ethylene, phthalonitrile, fumaronitrile, pyridine, pyrazine, triazine, bipyridine, terpyridine, ammonia, amines, alkyl amines, aryl amines, 1-aminopiperidine, hydrazine, ethylene diamine, 1,2-ethanediamine-N-(2-aminoethyl), tris(2-aminoethyl)amine, triethylamine, tetramethylethylenediamine, 1,4-diazabicyclo [2.2.2] octane (DABCO), triazinane, tetrakis(dimethylamino)ethylene, pyrazole, imidazole, pyrrole, 1,2,3-triazole, 1,2,4-triazole, pyrrole-2-carbonitrile, 1-(2-cyanoethyl) pyrrole, 2,6-pyridinedicarbonitrile, 2-[(methylamine)methyl]pyridine, diaminomaleonitrile, 2-pyridinecarbonitrile, N-methyl-pyrrole-2-carbonitrile, 2-pyrmidinecarbonitrile, alkyl alcohol, aryl alcohol, tetrahydrofuran borane, amino borane, dimethyl sulfide borane, phosphino borane, phenylsilane, diisopropylaminosilane, bi(diethylamino)silane, diethylmethylsilane, triethylsilane, alkyl aldehyde, aryl aldehyde, acetone, tetrahydrofuran, and the like.

At operation 115, the processing chamber is optionally purged after exposure to the reactant. Purging the processing chamber in operation 115 can be the same process or different process than the purge in operation 114. Purging the processing chamber, portion of the processing chamber, area adjacent the substrate surface, etc., removes unreacted reactants, reaction products and by-products from the area adjacent the substrate surface.

At operation 117, the substrate is optionally exposed to an atmosphere of hydrogen (H₂(g)) to react with the ruthenium-containing precursor and halide-free reactant in a reductive elimination reaction to leave a ruthenium film on the substrate surface.

At operation 118, the processing chamber is optionally purged after exposure to the reactant. Purging the processing chamber in operation 118 can be the same process or different process than the purge in operation 114, 115. Purging the processing chamber, portion of the processing chamber, area adjacent the substrate surface, etc., removes unreacted reactants, reaction products and by-products from the area adjacent the substrate surface.

At decision 120, the thickness of the deposited film, or number of cycles of ruthenium-containing precursor and halide-free reactant is considered. If the deposited film has reached a predetermined thickness or a predetermined number of process cycles have been performed, the method 100 moves to an optional post-processing operation 130. In some embodiments, the process cycle comprises sequential exposure of the substrate to ruthenium-containing precursor, purge gas, halide-free reactant, and purge gas. If the thickness of the deposited film or the number of process cycles has not reached the predetermined threshold, the method 100 returns to operation 110 to expose the substrate surface to the ruthenium-containing precursor again in operation 112 and continuing.

In one or more embodiments, the method 100 comprises a pulse of a ruthenium-containing precursor of general formula (I) L₁L₂Ru using a carrier gas comprising a mixture of argon (Ar) and hydrogen (H₂) for about 3 seconds, purging the substrate using a purge gas comprising a mixture of argon (Ar) and hydrogen (H₂), a pulse of a halide-free reactant using a carrier gas comprising a mixture of argon (Ar), hydrogen (H₂), and halide-free reactant for about 1 second, and purging the substrate using a purge gas comprising a mixture of argon (Ar) and hydrogen (H₂). In other embodiments, the method 100 comprises a pulse of a ruthenium-containing precursor of general formula (I) L₁L₂Ru using a carrier gas comprising a mixture of argon (Ar) and hydrogen (H₂) for about 3 seconds, purging the substrate using a purge gas comprising a mixture of (Ar) and hydrogen (H₂), a pulse of a halide-free reactant using a carrier gas comprising hydrogen (H₂) and the halide-free reactant for about 1 second, and purging the substrate using a purge gas comprising hydrogen (H₂).

In specific embodiments, the method 100 comprises a pulse of a ruthenium-containing precursor of general formula (I) L₁L₂Ru using a carrier gas comprising a mixture of argon (Ar) and hydrogen (H₂) for about 3 seconds, purging the substrate using a purge gas comprising a mixture of argon (Ar) and hydrogen (H₂), a pulse of a halide-free reactant using a carrier gas comprising a mixture of argon (Ar), hydrogen (H₂), and halide-free reactant for about 1 second, and purging the substrate using a purge gas comprising a mixture of argon (Ar) and hydrogen (H₂). In other embodiments, the method 100 comprises a pulse of a ruthenium-containing precursor of general formula (I) L₁L₂Ru using a carrier gas comprising a hydrogen (H₂) for about 3 seconds, purging the substrate using a purge gas comprising hydrogen (H₂), a pulse of a halide-free reactant using a carrier gas comprising hydrogen (H₂), and halide-free reactant for about 1 second, and purging the substrate using a purge gas comprising hydrogen (H₂). It has been advantageously found that performing method 100 in accordance with one or more embodiments, such as in specific embodiments, yields a ruthenium-containing film that forms selectively on a metal surface relative to a dielectric surface.

The optional post-processing operation 130 can be, for example, a process to modify film properties (e.g., annealing) or a further film deposition process (e.g., additional ALD or CVD processes) to grow additional films. In some embodiments, the optional post-processing operation 130 can be a process that modifies a property of the deposited film. In some embodiments, the optional post-processing operation 130 comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

The method 100 can be performed at any suitable temperature depending on, for example, the ruthenium-containing precursor of general formula (I) L₁L₂Ru, halide-free reactant, or thermal budget of the device. In one or more embodiments, the use of high temperature processing may be undesirable for temperature-sensitive substrates, such as logic devices. In some embodiments, exposure to the ruthenium-containing precursor of general formula (I) L₁L₂Ru (operation 112) and the halide-free reactant (operation 116) occur at the same temperature. In some embodiments, the substrate is maintained at a temperature in a range of about 20° C. to about 400° C., or about 50° C. to about 650° C.

In some embodiments, exposure to the ruthenium-containing precursor of general formula (I) L₁L₂Ru (operation 112) occurs at a different temperature than the exposure to the halide-free reactant (operation 116). In some embodiments, the substrate is maintained at a first temperature in a range of about 20° C. to about 400° C., or about 50° C. to about 650° C., for the exposure to the ruthenium-containing precursor of general formula (I) L₁L₂Ru, and at a second temperature in the range of about 20° C. to about 400° C., or about 50° C. to about 650° C., for exposure to the halide-free reactant.

In the embodiment illustrated in FIG. 1, at deposition operation 110 the substrate (or substrate surface) is exposed to the ruthenium-containing precursor of general formula (I) L₁L₂Ru and the halide-free reactant sequentially. In another, un-illustrated, embodiment, the substrate (or substrate surface) is exposed to the ruthenium-containing precursor of general formula (I) L₁L₂Ru and the halide-free reactant simultaneously in a CVD reaction. In a CVD reaction, the substrate (or substrate surface) can be exposed to a gaseous mixture of the ruthenium-containing precursor of general formula (I) L₁L₂Ru and halide-free reactant to deposit a ruthenium-containing film having a predetermined thickness. In the CVD reaction, the ruthenium-containing film can be deposited in one exposure to the mixed reactive gas or can be multiple exposures to the mixed reactive gas with purges between.

In some embodiments, the ruthenium-containing film formed comprises elemental ruthenium. Stated differently, in some embodiments, the ruthenium-containing film comprises a metal film comprising ruthenium. In some embodiments, the metal film consists essentially of ruthenium. As used in this manner, the term “consists essentially of ruthenium” means that the ruthenium-containing film is greater than or equal to about 80%, 85%, 90%, 95%, 98%, 99% or 99.5% ruthenium, on an atomic basis. Measurements of the composition of the ruthenium-containing film refer to the bulk portion of the film, excluding interface regions where diffusion of elements from adjacent films may occur.

The deposition operation 110 can be repeated to form a ruthenium-containing film having a predetermined thickness. In some embodiments, the deposition operation 110 is repeated to provide one or more of a ruthenium-containing film, such as a film comprising ruthenium metal (elemental ruthenium), ruthenium oxide (RuOₓ), ruthenium carbide (RuCₓ), ruthenium carbonitride (RuCₓN_{y}), ruthenium silicide (RuSiₓ), ruthenium carbosilicide (RuCₓSi_{y}), ruthenium sulfide (RuSₓ), ruthenium carbosulfide (RuCₓS_{y}), ruthenium nitride (RuNₓ), ruthenium phosphide (RuPₓ), or ruthenium carbophosphide (RuCₓP_{y}), having a thickness in the range of about 0.3 nm to about 100 nm, or in the range of about 30 Å to about 10 μm.

One or more embodiments of the disclosure are directed to methods of depositing ruthenium-containing films in high aspect ratio features. A high aspect ratio feature is a trench, via or pillar having a height:width ratio greater than or equal to about 10, 20, 50, 100, or more. In some embodiments, the ruthenium-containing film is deposited conformally on the high aspect ratio feature. As used in this manner, a conformal film has a thickness near the top of the feature that is in the range of about 80 to 120% of the thickness at the bottom of the feature.

Some embodiments of the disclosure are directed to methods for bottom-up gap fill of a feature. A bottom-up gap fill process fills the feature from the bottom versus a conformal process which fills the feature from the bottom and sides. In some embodiments, the feature has a first material at the bottom (e.g., a nitride) and a second material (e.g., an oxide) at the sidewalls. The ruthenium-containing film deposits selectively on the first material relative to the second material so that the ruthenium-containing film fills the feature in a bottom-up manner.

FIGS. 1A-1C illustrate cross-sectional schematic views of a substrate 50 during stages of a method of depositing a ruthenium-containing film 54. FIG. 1A illustrates a cross-sectional schematic view of depositing the ruthenium-containing film 54 on a top surface 52 of the substrate 50. As will be described in further detail below, the ruthenium-containing film 54 is formed by exposing the substrate 50 to a ruthenium-containing precursor and a reactant.

FIGS. 1B-1C illustrate a cross-sectional schematic view of depositing the ruthenium-containing film 54 on a top surface 52 of a substrate 50 comprising at least one feature 51. The at least one feature 51 defines a gap having two opposed sidewalls 64 and a bottom surface 61.

The two opposing sidewalls 64 may comprise any suitable material. In one or more embodiments, the two opposed sidewalls 64 comprise a dielectric material, e.g., a low-K dielectric material such as, but not limited to, silicon oxide (SiOx), silicon sub-oxides, silicon nitride (SiₓN_{y}), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof. The bottom surface 61 may comprise any suitable material, such as a metallic material.

FIGS. 1B-1C show the substrate 50 having a single feature 51 for illustrative purposes; however, those skilled in the art will understand that there can be more than one feature 51. The shape of the feature 51 can be any suitable shape including, but not limited to, trenches and cylindrical vias, as described herein.

In one or more embodiments, the at least one feature 51 comprises one or more of a trench or a via. In specific embodiments, the at least one feature 51 comprises a trench. In still further embodiments, the term “at least one feature 51” and “trench 51” may be used interchangeably. The trench 51 has a depth to the bottom surface 61 and a width between the two opposed sidewalls 64. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In one or more embodiments, the aspect ratio of the trench 51 described herein is greater than or equal to about 1:1, 2:1, 5:1, 10:1, 15:1, 20:1, 25:1, 30:1, 35:1, or 40:1.

It will be appreciated by the skilled artisan that the method that is part of a gap fill process can include one or more subsequent operations after forming the ruthenium-containing film 54, such as, for example, filling the gap with a conductive material, and that the one or more subsequent operations can be performed without undue experimentation.

FIGS. 2B-2E illustrate stages of manufacture of the microelectronic device 200 during the method 10 of FIG. 2A, and, more particularly, refer to methods of manufacturing interconnect structures as part of a microelectronic device fabrication process.

Referring to FIG. 2A, the method 10 comprises, at operation 12, pre-cleaning a substrate 210. In one or more embodiments, keeping the pre-cleaning process under vacuum ensures that no oxide is introduced/formed on the substrate 210 during the method 10. At operation 12, pre-cleaning the substrate 210 removes native oxides from the surface of the substrate 210.

The pre-cleaning process of operation 12 can be any suitable process. In some embodiments, the pre-cleaning process of operation 12 removes polymeric residues and copper oxide from the interconnect and maintains the integrity of the dielectric surface. As used herein, the term “substrate 210” can be used to refer to a substrate and/or a pre-cleaned substrate, unless the context clearly indicates otherwise.

At operation 14, the method 10 comprises forming a dielectric layer 245 on the substrate 210, e.g., the pre-cleaned substrate. The dielectric layer 245 comprises at least one feature defining a gap 246 having sidewalls 248 and a bottom 249. At operation 16, the method 10 comprises forming a blocking layer 250 on the bottom 249 by exposing the substrate 210 to a blocking compound. At operation 18, the method 10 comprises selectively depositing a ruthenium-containing film 260 on the sidewalls 248. At operation 20, the method 10 comprises removing the blocking layer 250. At operation 22, the method 10 comprises performing a gap fill process to fill the gap 246 with a gap fill material 280.

In one or more embodiments, the method 10 comprises operation 12, operation 14, operation 16, operation 18, operation 20, and operation 22. In one or more embodiments, the method 10 consists essentially of operation 12, operation 14, operation 16, operation 18, operation 20, and operation 22. In one or more embodiments, the method 10 consists of operation 12, operation 14, operation 16, operation 18, operation 20, and operation 22. In one or more embodiments, the method 10 consists of operation 16 (where the dielectric layer 245 on the substrate 210, e.g., a pre-cleaned substrate, is provided), operation 18, operation 20, and operation 22.

Referring to FIGS. 2B-2E, a portion of the microelectronic device 200 is shown during stages of manufacture. In FIG. 2B, the microelectronic device 200 comprises the substrate 210, a barrier layer 220 on the substrate 210, a metal layer 230 on the barrier layer 220, a conductive filled gap 240, an etch stop layer 242, and the dielectric layer 245 on the etch stop layer 242. The dielectric layer 245 comprises at least one feature defining the gap 246 having sidewalls 248 and the bottom 249. According to one or more embodiments, a blocking layer 250 is formed on the bottom 249 of the gap 246. It will be appreciated that in one or more embodiments, the conductive filled gap 240 forms a metal line that transfers current within the same device layer.

In one or more embodiments, the substrate 210 is a wafer, for example, a semiconductor substrate. In one or more embodiments, the substrate 210 is an etch stop layer on a wafer. In one or more embodiments, the substrate 210 is an aluminum oxide etch stop layer on a wafer.

In one or more embodiments, the barrier layer 220 comprises tantalum nitride (TaN). In one or more embodiments, the barrier layer 220 comprises tantalum nitride (TaN) formed by ALD.

In one or more embodiments, the metal layer 230 comprises one or more of ruthenium (Ru), copper (Cu), cobalt (cobalt), ruthenium (Ru), tantalum (Ta), or tungsten (W). In one or more embodiments, the metal layer 230 comprises one or more of copper (Cu), cobalt (cobalt), ruthenium (Ru), or tungsten (W). In one or more embodiments, a portion of the metal layer 230 is etched. In one or more embodiments, the blocking layer 250 is deposited on the portion of the metal layer 230 that is etched. In one or more embodiments, the conductive filled gap 240 comprises one or more of copper (Cu) or cobalt (Co). In one or more embodiments, the etch stop layer 242 comprises one or more of aluminum oxide, silicon nitride, or aluminum nitride.

In one or more embodiments, the dielectric layer 245 comprises a low-K dielectric material. In one or more embodiments, the dielectric layer 245 comprises silicon oxide (SiOₓ). In one or more embodiments, the dielectric layer 245 comprises SiOₓH_{y}(CH_{z}). Further embodiments provide that the dielectric layer 245 comprises porous or carbon-doped SiOₓ. In some embodiments, the dielectric layer 245 is a porous or carbon-doped SiOₓ layer with a K value less than about 5. In other embodiments, the dielectric layer 245 is a multilayer structure. For example, in one or more embodiments, the dielectric layer 245 comprises a multilayer structure having one or more of a dielectric layer, an etch stop layer, and a hard mask layer.

In one or more illustrated embodiments, the dielectric layer 245 comprises at least one feature defining the gap 246 having sidewalls 248 and the bottom 249. FIGS. 2A-2E illustrate substrate 210 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 1:1, 2:1, 5:1, 10:1, 15:1, 20:1, 25:1, 30:1, 35:1 or 40:1.

In some embodiments, the at least one feature defines a cylindrical via that, when filled with metal, transfers current between layers, and lines that transfer current within the same device layer. In some embodiments, the at least one feature defines the gap 246 in the dielectric layer 245. In some embodiments, the gap 246 defines a via portion 246V and a line portion 246L.

The bottom 249 of the gap 246 is defined by the metal layer 230. In one or more embodiments, the bottom 249 of the gap 246 and the metal layer 230 comprise the same material. In one or more embodiments, the bottom 249 of the gap 246 comprises one or more of ruthenium (Ru), copper (Cu), cobalt (cobalt), ruthenium (Ru), tantalum (Ta), or tungsten (W). In one or more embodiments, the bottom 249 of the gap 246 comprises one or more of copper (Cu), cobalt (cobalt), ruthenium (Ru), or tungsten (W).

In one or more embodiments, the blocking layer 250 is formed on the bottom 249 of the gap 246 in accordance with operation 16 of the method 10 (FIGS. 2A and 2B). Stated differently, in one or more embodiments, the blocking layer 250 is formed on the metal layer 230, which defines the bottom 249 of the gap 246. In one or more embodiments, the portion of the metal layer 230 on which the blocking layer 250 is formed defines the bottom 249 of the gap 246. In one or more embodiments, the blocking layer 250 is formed selectively on the bottom 249 of the gap 246 by exposing the substrate 210 to a blocking compound.

Embodiments of the present disclosure employ blocking compounds that can be used to form a blocking layer on a surface to suppress or prevent subsequent deposition on that surface. Any blocking compound that suppresses or prevents subsequent deposition on a metallic surface, e.g., the metal layer 230, which defines the bottom 249 of the gap 246 may be used.

In some embodiments, the blocking compound comprises one or more of organic ligands or inorganic ligands. In some embodiments, the blocking compound comprises organic ligands. In some embodiments, the blocking compound comprises at least one ketone group. In some embodiments, the blocking compound comprises at least one alkoxy group. In some embodiments, the blocking compound comprises at least one heterocyclic carbene group. In some embodiments, the blocking compound comprises inorganic ligands. In some embodiments, the blocking compound comprises a silicon-containing compound. In some embodiments, the blocking compound comprises at least one silane group. In some embodiments, the blocking compound comprises at least one thiol group. In some embodiments, the blocking compound comprises a phosphonate-containing compound.

In one or more embodiments, the blocking compound comprises a formula R₁—C≡C—R₂, wherein R₁ and R₂ are linear alkyl chains comprising from 5 to 15 carbon atoms. In one or more embodiments, the blocking compound comprises a formula H—C≡C—R₃, wherein R₃ is a linear alkyl chain comprising from 1 to 20 carbon atoms. In one or more embodiments, the blocking compound has a formula of R—SiH₃, wherein R is selected from a linear alkyl chain and a branched alkyl chain comprising from 2 to 20 carbon atoms.

In some embodiments, the processing conditions for exposing the substrate 210 to the blocking compound to form the blocking layer 250 may be controlled and may be varied depending on the composition of the blocking compound.

The substrate 210 may be exposed to the blocking compound at any suitable pressure for forming the blocking layer 250. In some embodiments, the substrate 210 is exposed to the blocking compound at a pressure of less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr.

The substrate 210 may be exposed to the blocking compound for any suitable time period to form the blocking layer 250 to a predetermined thickness. In some embodiments, the substrate 210 is exposed to the blocking compound for a time period in a range of from 1 second to 600 seconds.

The substrate 210 may be exposed to the blocking compound at any suitable temperature to form the blocking layer 250. In some embodiments, the substrate 210 is exposed to the blocking compound at a temperature in a range of 150° C. to 400° C., such as, for example, in a range of from 200° C. to 300° C.

The blocking layer 250 may be formed using any suitable deposition technique. In one or more embodiments, the blocking layer 250 is formed in an atomic layer deposition (ALD) chamber. In one or more embodiments, the blocking layer 250 is formed in an ex situ solution processing chamber.

Referring to FIGS. 2A and 2C, at operation 18 of the method 10, the ruthenium-containing film 260 is selectively deposited on the sidewalls 248 of the gap 246. In one or more embodiments, the ruthenium-containing film 260 covers the entirety of the sidewalls 248. In one or more embodiments, the ruthenium-containing film 260 does not form on the bottom 249 of the gap 246 due to the presence of the blocking layer 250 on the metal layer 230, which defines the bottom 249 of the gap 246.

The ruthenium-containing film 260 may be selectively deposited using any suitable deposition technique. In one or more embodiments, the ruthenium-containing film 260 is formed by exposing the substrate 210 to a ruthenium-containing precursor and a reactant.

In one or more embodiments, the ruthenium-containing precursor is a precursor of general formula (I) L₁L₂Ru, where L₁ is a benzene derivative having at least one alkyl group substitute on the benzene ring. The alky group can comprise any suitable alkyl such as, but not limited to, methyl, ethyl, propyl, isopropyl, and the like. In one or more embodiments, the alkyl group is defined as R³, where R³ is an alkyl chain from 1 to 10 carbons in length. In one or more embodiments, L₂ is any suitable diene, such as, but not limited to, butadiene, cyclobutadiene, isoprene, 1,3-pentadiene, cyclohexadiene, 1,5-cyclooctadiene. In one or more embodiments, the reactant comprises any suitable sp-hybridized reactant.

In one or more embodiments, the substrate 210 is exposed to the ruthenium-containing precursor and the reactant simultaneously. In one or more embodiments, the substrate 210 is exposed to the ruthenium-containing precursor and the reactant sequentially.

The reactant according to one or more embodiments is a thermal reactant (e.g., without the use of plasma) or a plasma composed of the reactant. In embodiments where the reactant comprises a plasma composed of the reactant, the plasma may be generated by any suitable plasma source. The plasma may include, but is not limited to, one or more of an inductively coupled plasma (ICP) source, a capacitively coupled plasma (CCP) source, a microwave source, or a remote plasma source.

In one or more embodiments, the reactant comprises any of the halide-free reactants described above with respect to method 100. More specifically, in one or more embodiments, the halide-free reactants may be one or more of an sp-hybridized N-containing ligand, a sp2-hybridized N-containing ligand, a sp3-hybridized N-containing ligand, a mixed-hybridized N-containing ligand, an alcohol, a silane, a borane, and the like.

The sp-hybridized N-containing ligand may be any suitable sp-hybridized N-containing ligand. In one or more embodiments, the sp-hybridized N-containing ligand may be selected from:

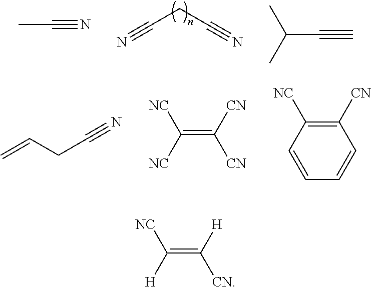

The sp2-hybridized N-containing ligand may be any suitable sp2-hybridized N-containing ligand. In one or more embodiments, the sp2-hybridized N-containing ligand may be selected from one or more of:

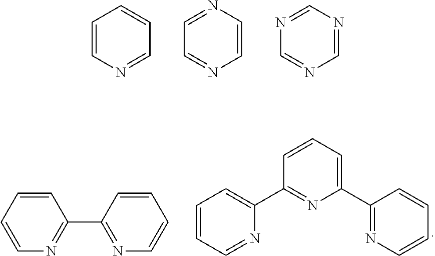

The sp3-hybridized N-containing ligand may be any suitable sp3-hybridized N-containing ligand. In one or more embodiments, the sp3-hybridized N-containing ligand may be selected from one or more of:

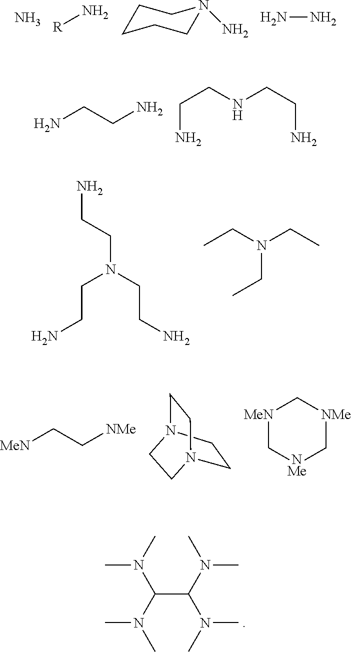

The mixed-hybridized N-containing ligand may be any suitable mixed-hybridized N-containing ligand. In one or more embodiments, the mixed-hybridized N-containing ligand may be selected from:

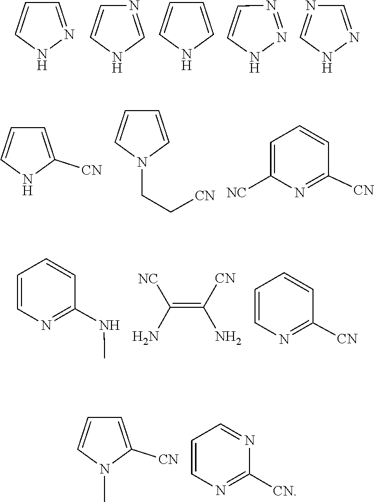

The alcohol may be any suitable alcohol. In one or more embodiments, the alcohol may be selected from R—OH where R comprises an alkyl or aryl group containing from 1 to 10 carbon atoms.

The silane may be any suitable silane. In one or more embodiments, the silane may be selected from

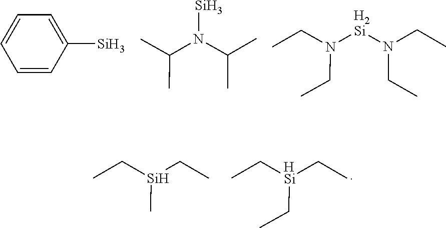

The borane may be any suitable borane. In one or more embodiments, the borane may be selected from:

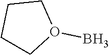

R₃N—BH₃ Me₂S—BH₃ R₃P—BH₃ where R independently comprises an alkyl or aryl group containing from 1 to 10 carbon atoms.

In one or more embodiments, other possible reactants may include

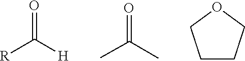

where R comprises an alkyl or aryl group containing from 1 to 10 carbon atoms.

The halide-free reactant may be selected from one or more of acetonitrile, malononitrile, succinonitrile, glutaronitrile, adiponitrile, tertiarybutyl isocyanide, allyl nitrile, tetracyano ethylene, phthalonitrile, fumaronitrile, pyridine, pyrazine, triazine, bipyridine, terpyridine, ammonia, amines, alkyl amines, aryl amines, 1-aminopiperidine, hydrazine, ethylene diamine, 1,2-ethanediamine-N-(2-aminoethyl), tris(2-aminoethyl)amine, triethylamine, tetramethylethylenediamine, DABCO, triazinane, tetrakis(dimethylamino)ethylene, pyrazole, imidazole, pyrrole, 1,2,3-triazole, 1,2,4-triazole, pyrrole-2-carbonitrile, 1-(2-cyanoethyl) pyrrole, 2,6-pyridinedicarbonitrile, 2-[(methylamine)methyl]pyridine, diaminomaleonitrile, 2-pyridinecarbonitrile, N-methyl-pyrrole-2-carbonitrile, 2-pyrmidinecarbonitrile, alkyl alcohol, aryl alcohol, tetrahydrofuran borane, amino borane, dimethyl sulfide borane, phosphino borane, phenylsilane, diisopropylaminosilane, bi(diethylamino)silane, diethylmethylsilane, triethylsilane, alkyl aldehyde, aryl aldehyde, acetone, tetrahydrofuran, and the like.

Advantageously, the ruthenium-containing film 260 acts as a barrier layer and/or metal liner and prevents conductive metal, such as, for example, one or more of copper (Cu), cobalt (Co), ruthenium (Ru), tungsten (W), or ruthenium (Ru), from diffusing into the dielectric layer 245.

The ruthenium-containing film 260 described herein can extend the metal fill and capping applications to advanced nodes, such as enabling conductive metal reflow, e.g., one or more of copper (Cu), cobalt (Co), tungsten (W), ruthenium (Ru), and/or ruthenium (Ru) reflow, in 3 nm node, 2 nm node, 1.4 nm node, and beyond, low resistivity in the middle-of-line (MOL) and back-end of line (BEOL), and memory applications.

The ruthenium-containing film 260 may be formed at any suitable processing conditions, and the processing conditions may vary depending upon the application in which the ruthenium-containing film 260 is used. The processing conditions may also vary depending on the composition of the ruthenium-containing precursor and the reactant.

The substrate 210 may be exposed to the ruthenium-containing precursor and the reactant at any suitable temperature for forming the ruthenium-containing film 260. In one or more, the substrate 210 is exposed to the ruthenium-containing precursor and the reactant at a temperature in a range of from 100° C. to 500° C.

The substrate 210 may be exposed to the ruthenium-containing precursor and the reactant at any suitable pressure for forming the ruthenium-containing film 260. In one or more, the substrate 210 is exposed to the ruthenium-containing precursor and the reactant at a pressure in a range of from 0.1 Torr to 760 Torr.

In some embodiments, the ruthenium-containing film 260 comprises greater than or equal to about 95 atomic percent ruthenium, or greater than or equal to about 97 atomic percent ruthenium, or greater than or equal to about 98 atomic percent ruthenium, or greater than or equal to about 99 atomic percent ruthenium, or greater than or equal to about 99.5 atomic percent ruthenium, or greater than or equal to about 99.8 atomic percent ruthenium.

In some embodiments, the ruthenium-containing film 260 contains essentially no halogen atoms. As used in this manner, the term “contains essentially no halogen atoms” means the ruthenium-containing film 260 about 0% of halogen atoms on an atomic basis. In some embodiments, the ruthenium-containing film 260 is free of halogen atoms. It is noted that, as recognized by one of skill in the art, while the reactant and ruthenium-containing precursor do not contact halogen atoms, a halide contaminant could be present from another source. Thus, the ruthenium-containing film 260 may contain a small amount, e.g., less than 5% on an atomic basis, of a halide contaminant.

The ruthenium-containing film 260 may have any suitable thickness. In one or more embodiments, the ruthenium-containing film 260 has a thickness in a range of from about 2 Å to about 50 Å. In some embodiments, the ruthenium-containing film 260 is deposited in a single ALD cycle. In other embodiments, the ruthenium-containing film 260 is deposited in from 1 to 200 ALD cycles. In one or more embodiments, each cycle of the 1 to 200 ALD cycles is configured to deposit a thickness of about 0.2 Å of the ruthenium-containing film 260.

In one or more embodiments, when the blocking layer 250 is not present, the deposition of the ruthenium-containing film 260 is substantially conformal, such that the ruthenium-containing film 260 forms on the sidewalls 248 and on the bottom 249 of the gap 246. As used herein, a layer which is “substantially conformal” refers to a layer where the thickness is about the same throughout (e.g., on the top, middle and bottom of sidewalls 248 and on the bottom 249 of the gap 246). A layer which is substantially conformal varies in thickness by less than or equal to about 5%, 2%, 1% or 0.5%.

As described herein, in one or more embodiments, the ruthenium-containing film 260 does not form on the bottom 249 of the gap 246 due to the presence of the blocking layer 250. The ruthenium-containing film 260 selectively forms on the sidewalls 248 and extends towards the bottom 249 of the gap 246.

Referring to FIGS. 2A and 2D, at operation 22 of the method 10, the blocking layer 250 is removed. In one or more embodiments, removing the blocking layer 250 comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases the density of the ruthenium-containing film 260.

Referring to FIGS. 2A and 2E, the method 10 includes performing a gap fill process to fill the gap 246 with a gap fill material 280 (operation 22). The gap fill process can include any suitable deposition technique. In one or more embodiments, the gap fill process comprises a physical vapor deposition (PVD) process.

The gap fill material 280 may include any suitable material, such as a conductive material. In one or more embodiments, the gap fill material 280 comprises one or more of copper (Cu), cobalt (Co), ruthenium (Ru), tungsten (W), or ruthenium (Ru). In one or more embodiments, the gap fill process comprises filling the gap 246 with one or more of copper (Cu), cobalt (Co), ruthenium (Ru), tungsten (W), or ruthenium (Ru) by physical vapor deposition (PVD). In one or more embodiments, the gap fill process comprises filling the gap 246 with one or more of copper (Cu), cobalt (Co), tungsten (W), or ruthenium (Ru) by physical vapor deposition (PVD).

The gap fill material 280 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gap fill material 280 an atomic basis, comprises seams and/or voids. Advantageously, in one or more embodiments, the gap fill material 280 is free of seams and/or voids.

In one or more embodiments, after filling the gap 246 with the gap fill material 280, a completed interconnect structure, e.g., interconnect structure 290 is formed, such that additional interconnect structures may be formed on top of or below the interconnect structure 290.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film/layer. In some embodiments, the optional post-processing operation comprises annealing the substrate. In some embodiments, the annealing process is performed at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers, such as ruthenium-containing film 260.

In some embodiments, the substrate is moved from a first chamber to a separate, next chamber for further processing. The substrate can be moved directly from the first chamber to the separate processing chamber, or the substrate can be moved from the first chamber to one or more transfer chambers and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein.

Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc., processes throughout the carousel path.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Additional embodiments are directed to a cluster tool used to manufacture the microelectronic devices described herein, e.g., microelectronic device 200, and perform the methods described herein, e.g., method 10. In one or more embodiments, the cluster tool comprises a pre-cleaning chamber to pre-clean the substrate and a deposition chamber for forming a dielectric layer including at least one feature defining a gap having sidewalls and a bottom. In one or more embodiments, a pre-cleaned substrate comprising a dielectric layer including at least one feature defining a gap having sidewalls and a bottom is provided.

In one or more embodiments, the cluster tool comprises a deposition chamber for forming a blocking layer 250. In one or more embodiments, the cluster tool comprises an atomic layer deposition (ALD) chamber for forming the blocking layer 250. In one or more embodiments, the cluster tool comprises an atomic layer deposition (ALD) chamber for selectively depositing the ruthenium-containing film 260. In one or more embodiments, the cluster tool comprises a chamber for removing the blocking layer. Advantageously, in one or more embodiments, the same processing chamber may be used to selectively deposit the ruthenium-containing film 260 and to remove the blocking layer. In one or more embodiments, the cluster tool comprises a deposition chamber for performing the gap fill process to fill the gap with a gap fill material. In one or more embodiments, the cluster tool comprises a physical vapor deposition (PVD) chamber for performing the gap fill process to fill the gap with a gap fill material.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein with respect to FIGS. 1, 1A-1C, and 2A-2E.

### EXAMPLES

### Example 1: Atomic Layer Deposition of Ruthenium-Containing Films

General procedure: A silicon substrate is placed in a processing chamber. A ruthenium-containing precursor of general formula (I) L₁L₂Ru is flowed into the processing chamber in an atmosphere of nitrogen (N₂) gas over the silicon substrate leaving a ruthenium-precursor terminated surface. Unreacted precursor and byproducts are then purged out of the chamber. Next, a halide-free co-reactant is then introduced into the chamber that reacts with the surface-bound ruthenium species. Again, excess halide-free co-reactant and byproducts are removed from the chamber. The resultant material on the substrate is a ruthenium-containing film.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of depositing a ruthenium-containing film, the method comprising:
exposing a semiconductor substrate to a ruthenium-containing precursor and a reactant to form the ruthenium-containing film, the ruthenium-containing precursor having a general formula (I) L₁L₂Ru, wherein L₁ is a benzene substituted with at least one alkyl group, L₂ is diene, and the reactant comprises one or more of an sp-hybridized N-containing ligand, an sp2-hybridized N-containing ligand, an sp3-hybridized N-containing ligand, a mixed-hybridized N-containing ligand, an alcohol, a silane, a borane, and other reactant.

2. The method of claim 1, wherein the benzene is substitute with at least one alkyl group comprising from 1 to 10 carbon atoms.

3. The method of claim 2, wherein the alkyl group is selected from one or more of methyl, ethyl, propyl, isopropyl, butyl, and pentyl.

4. The method of claim 1, wherein L₂ is a diene selected from the group consisting of butadiene, cyclobutadiene, isoprene, 1,3-pentadiene, cyclohexadiene, 1,5-cyclooctadiene.

5. The method of claim 1, wherein the semiconductor substrate comprises at least one feature, the at least one feature defining a gap having sidewalls and a bottom.

6. The method of claim 5, wherein the sidewalls comprise a dielectric material and the bottom comprises a metallic material.

7. The method of claim 1, wherein the semiconductor substrate is exposed to the ruthenium-containing precursor and the reactant simultaneously.

8. The method of claim 1, wherein the semiconductor substrate is exposed to the ruthenium-containing precursor and the reactant sequentially.

9. The method of claim 5, wherein the ruthenium-containing film forms conformally along the sidewalls and the bottom of the gap.

10. The method of claim 1, wherein the reactant is a thermal reactant or a plasma composed of the reactant.

11. The method of claim 1, wherein the sp-hybridized N-containing ligand may be selected from:

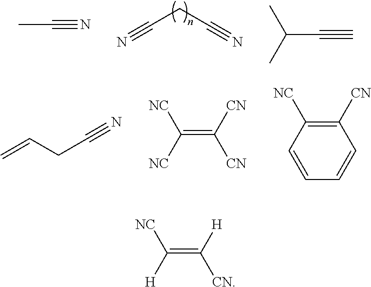

12. The method of claim 1, wherein the sp2-hybridized N-containing ligand is selected from one or more of:

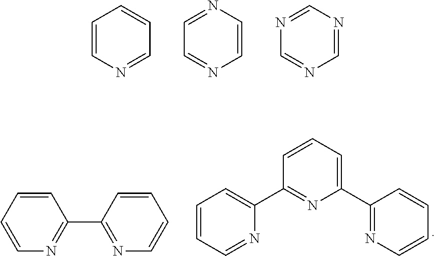

13. The method of claim 1, wherein the sp3-hybridized N-containing ligand is selected from one or more of:

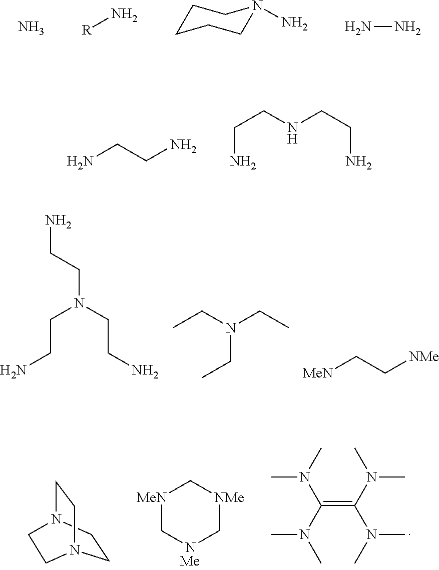

14. The method of claim 1, wherein the mixed-hybridized N-containing ligand is selected from:

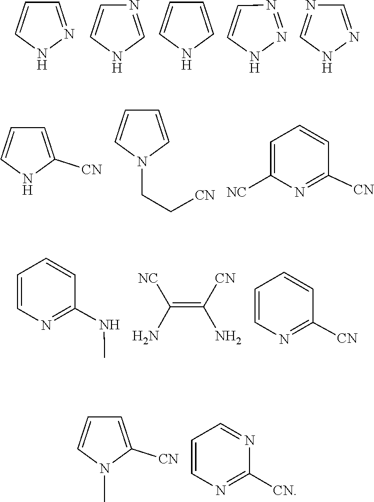

15. The method of claim 1, wherein the alcohol is selected from where R—OH were R comprises an alkyl or aryl group containing from 1 to 10 carbon atoms.

16. The method of claim 1, wherein the silane is selected from

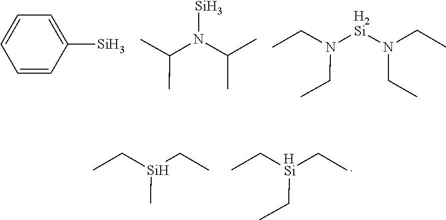

17. The method of claim 1, wherein the borane is selected from: 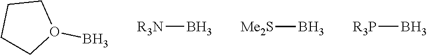
where R independently comprises an alkyl or aryl group containing from 1 to 10 carbon atoms.

18. The method of claim 1, wherein the other reactant is selected from 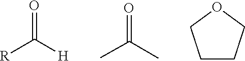
where R comprises an alkyl or aryl group containing from 1 to 10 carbon atoms.

19. The method of claim 1, wherein the ruthenium-containing film comprises greater than or equal to about 99% ruthenium atoms.

20. A method of manufacturing a microelectronic device, the method comprising:
forming a dielectric layer on a substrate, the dielectric layer including at least one feature defining a gap having sidewalls and a bottom;
forming a blocking layer on the bottom;
selectively depositing a ruthenium-containing film on the sidewalls by exposing the substrate to a ruthenium-containing precursor and a reactant, the ruthenium-containing precursor having a general formula (I) L₁L₂Ru, wherein L₁ is a benzene substituted with at least one alkyl group, L₂ is diene, and the reactant comprising one or more of an sp-hybridized N-containing ligand, an sp2-hybridized N-containing ligand, an sp3-hybridized N-containing ligand, a mixed-hybridized N-containing ligand, an alcohol, a silane, a borane, and other reactants;
removing the blocking layer; and
performing a gap fill process to fill the gap with a gap fill material comprising one or more of copper (Cu), cobalt (Co), ruthenium (Ru), tungsten (W), or ruthenium (Ru).
